(19) United States
(12) Patent Application Publication
(10) Pub. No.: US 2024/0012326 A1
(43) Pub. Date: Jan. 11, 2024

(54) PHOTOSENSITIVE ELEMENT, AND METHOD FOR FORMING RESIST PATTERN

(71) Applicant: ASAHI KASEI KABUSHIKI KAISHA, Tokyo (JP)

(72) Inventor: Shota YANAGI, Tokyo (JP)

(73) Assignee: ASAHI KASEI KABUSHIKI KAISHA, Tokyo (JP)

(21) Appl. No.: 18/271,018

(22) PCT Filed: Jan. 25, 2022
(86) PCT No.: PCT/JP2022/002691

§ 371 Date: Jul. 5, 2023

(30) Foreign Application Priority Data
Jan. 29, 2021 (JP) 2021-012929

(51) Int. Cl. G03F 7/027; H05K 3/10

(52) U.S. Cl. CPC G03F 7/027; H05K 3/10

(57) ABSTRACT

A photosensitive element including, in this order, a support film (A) and a photosensitive resin composition layer (B), wherein a developed interfacial ratio Sdr_{A2}(%) of an interface of the support film (A) on a side in contact with the photosensitive resin composition layer (B) and a developed interfacial ratio Sdr_{A1}(%) of an interface thereof on the opposite side as defined in ISO 25178 satisfy the following formula (1): Sdr_{A1}/Sdr_{A2}<0.75 (1)

### FIELD

The present invention relates to a photosensitive element and a resist pattern formation method.

### BACKGROUND

Printed wiring boards are used for the implementation of components and semiconductors in electronic devices such as personal computers and mobile phones. As the resist for producing printed wiring boards, conventionally, a photosensitive element (photosensitive resist laminate), i.e., a dry film resist, formed by laminating a photosensitive resin composition layer on a support film, and further laminating a protective film on the photosensitive resin composition layer as necessary is used.

In such a photosensitive element, since an exposure step of curing the photosensitive layer is performed via the support film, the characteristics of the support film greatly influence the resolution. Thus, as the support film, a film having a minimum amount of lubricant or internal foreign matter, which blocks the exposure light, is preferably used (refer to, for example, Patent Literature 1 to 4).

### CITATION LIST

### Patent Literature

[PTL 1] Japanese Patent No. 4014872
[PTL 2] WO 2018/100730
[PTL 3] Japanese Patent No. 5814667
[PTL 4] WO 2018/105620

### SUMMARY

### Technical Problem

As the resolution of printed substrate wiring has progressed, the compositions and blending amounts of compounds in photosensitive resin compositions have been studied. In recent years, compositions containing a large amount of styrene as a comonomer component in an alkali-soluble polymer for forming a photosensitive resin layer have preferably been used. Since styrene-based alkali-soluble polymers are not prone to swelling during alkali development, they are an essential component for achieving high resolution, but have problems regarding low adhesive strength with the support film and low tackiness, which makes them prone to detach from the photosensitive resin layer. In low-tackiness photosensitive elements, when the substrate is lifted by equipment during transport after lamination, the support film may peel, which can interfere with production. In order to increase tackiness, it is advantageous to increase the surface roughness of the surface of the support film contacting the photosensitive resin layer, because this increases the bonding surface area and enhances the anchor effect (the photosensitive resin layer penetrates into the fine irregularities of the support film to improve adhesion).

In recent years, the demand for high resolution has further increased, and L/S=5/5 μm or less has been required as the resolution of the developed resist. In fine resist patterns, it is advantageous for high resolution that the side surfaces of the resist pattern be flat and free of wrinkling, that is, that the sidewalls have excellent straightness, so as not to contact adjacent patterns.

Regarding improvements in the straightness of the sidewalls, the compositions and blending amounts of the compounds in the photosensitive resin composition have been studied, and while wrinkles of 1 μm or more have been alleviated to a certain extent, wrinkles of less than 1 μm have not yet been eliminated.

There are various factors which contribute to the wrinkling of sidewalls, and one factor is the influence of the support film. Conventionally, when exposing a photosensitive element, since the photosensitive resin layer is irradiated with actinic rays via the support film, if the support film refracts or scatters the light, the photosensitive resin layer will wrinkle. Regarding this problem, as a method of improving the straightness of the sidewalls without depending on improvement of the photosensitive element, a method of exposing with an exposure machine using a lens having a high numerical aperture is known. Since high numerical aperture lenses have a shallow depth of field, focusing only on the photosensitive resin layer minimizes the effects of support film refraction and scattering. Though such a method is effective on flat substrates such as wafers and glass substrates, copper-clad laminates, which are generally used for printed wiring boards, have large undulations and irregularities derived from organic base materials, and thus, there is a problem that defocusing tends to occur across the substrate as a whole. In points where defocusing occurs, the resolution of the resist pattern and the straightness of the sidewalls deteriorate significantly, it is reportedly difficult to apply an exposure machine (in particular, a projection exposure machine) using a lens with a high numerical aperture to organic substrates having large undulations.

Thus, it is preferable to solve the problem on the material side, and in order to achieve the high resolution demanded in recent years, there is a demand for a photosensitive element free of sidewall wrinkles of not only 1 μm or more but also of less than 1 μm.

The present invention has been proposed in light of such circumstances of the prior art, and an object of the present invention is to provide a photosensitive element in which a high tackiness and a high resolution are realized, and a resist pattern formation method.

### Solution to Problem

[1]

A photosensitive element, comprising, in this order, a support film (A) and a photosensitive resin composition layer (B), wherein
a developed interfacial ratio Sdr_{A1}(%) of an interface of the support film (A) on an opposite side to that in contact with the photosensitive resin composition layer (B) as defined in ISO 25178 is:

Sdr_{A1}<0.005(%).

[2]

A photosensitive element, comprising, in this order, a support film (A) and a photosensitive resin composition layer (B), wherein a developed interfacial ratio Sdr_{A2}(%) of an interface of the support film (A) on a side in contact with the photosensitive resin composition layer (B) and a developed interfacial ratio Sdr_{A1}(%) of an interface thereof on the opposite side as defined in ISO 25178 satisfy the following formula (1):

Sdr_{A1}/Sdr_{A2}<0.75 (1).

[3]

A photosensitive element, comprising, in this order, a support film (A) and a photosensitive resin composition layer (B), wherein
a surface particle number P_{A2} (particles) of 1.0 μm or more included in an area of 258 μm×260 μm of a surface of the support film (A) on a side in contact with the photosensitive resin composition layer (B) and a surface particle number P_{A1} (particles) of a surface thereof on the opposite side satisfy the following formula (2):

P_{A1}/P_{A2}<0.75 (2).

[4]

A photosensitive element, comprising, in this order, a support film (A) and a photosensitive resin composition layer (B), wherein
a maximum surface particle size S_{A2} (μm) of a surface of the support film (A) on a side in contact with the photosensitive resin composition layer (B) and a maximum surface particle size S_{A1} (μm) of a surface thereof on the opposite side satisfy the following formula (3):

S_{A1}/S_{A2}<0.75 (3).

[5]

The photosensitive element according to any one of [1] to [4], wherein a comonomer ratio of a structure having an aromatic ring in a binder of the photosensitive resin composition layer (B) is 50% or more.

[6]

The photosensitive element according to [5], wherein the structure having an aromatic ring is styrene.

[7]

A resist pattern formation method, comprising the following steps:
a lamination step of laminating the photosensitive element according to any one of [1] to [6] on a substrate,
an exposure step of exposing a photosensitive resin layer of the photosensitive element, and
a development step of removing an unexposed part of the photosensitive resin layer by development, wherein
the exposure step is carried out by a projection exposure method.
   [8]

A resist pattern formation method, comprising the following steps:
a lamination step of laminating the photosensitive element according to any one of [1] to [6] on a substrate,
an exposure step of exposing a photosensitive resin layer of the photosensitive element, and
a development step of removing an unexposed part of the photosensitive resin layer by development, wherein
the exposure step is carried out at an exposure wavelength of 405 nm or less.
   [9]

The photosensitive element according to any one of [1] to [6], wherein
the photosensitive element can be laminated on a copper substrate having a copper shield layer having an average thickness of 1 um or less, and
when the photosensitive element laminated on the copper substrate is subjected to:
(1) exposure using an exposure mask having exposed and unexposed parts with a pitch of 10 μm, and
(2) formation of lines/spaces of a photosensitive resin layer by development after the exposure, an average space width D_{W1} and a minimum space width D_{W2} satisfy the relationship: 1.00<D_{W1}/D_{W2}<1.10.

The photosensitive element according to any one of [1] to [6], wherein
the photosensitive element can be laminated on a copper substrate having a copper shield layer having an average thickness of 1 um or less, and when:
(1) exposure using an exposure mask having exposed and unexposed parts with a pitch of 10 μm,
(2) formation of lines/spaces of a photosensitive resin layer by development after the exposure,
(3) formation of a plating pattern by plate processing of the spaces, and
(4) peeling of the photosensitive resin layer from the substrate, are carried out,
an average pattern width P_{W1} of plating and a minimum pattern width P_{W2} of plating satisfy the relationship:

1.00<P_{W1}/P_{W2}<1.10.

The photosensitive element according to any one of [1] to [6], wherein
the photosensitive element can be laminated on a copper substrate having a copper shield layer having an average thickness of 1 um or less, and when:
(1) exposure using an exposure mask having exposed and unexposed parts with a pitch of 10 μm,
(2) formation of lines/spaces of a photosensitive resin layer by development after the exposure,
(3) formation of a plating pattern by plate processing of the spaces,
(4) peeling of the photosensitive resin layer from the substrate, and
(5) formation of a post-etch plating pattern, which remains after etching of the copper shield layer on the substrate after the peeling of the plating pattern, of the plating pattern, are carried out,
an average pattern width F_{W1} of post-etch plating and a minimum pattern width F_{W2} of post-etch plating satisfy the relationship:

1.00<F_{W1}/F_{W2}<1.10.

A method for the formation of a conductor pattern using the photosensitive element according to any one of [1] to [6], wherein
the photosensitive element can be laminated on a copper substrate having a copper shield layer having a thickness t (um),
when the photosensitive element laminated on the copper substrate is subjected to:
(1) exposure using an exposure mask having exposed and unexposed parts having a pitch of X (μm), and
(2) formation of lines/spaces of a photosensitive resin layer by development after the exposure, and
an average space width D_{W1} is {(±10% of (X/2))+t} or more, and when
(3) formation of a plating pattern by plate processing of the spaces, and
(4) peeling of the photosensitive resin layer from the substrate, are carried out,
an average pattern width P_{W1} of plating is within ±10% of the average space width D_{W1}.

A wiring pattern formation method, wherein when, after the method for the formation of a conductor pattern according to [12],
(5) formation of a post-etch plating pattern, which remains after etching of the copper shield layer on the substrate after the peeling of the plating pattern, of the plating pattern, is carried out,
an average pattern width F_{W1} of post-etch plating is less than the average pattern width P_{W1} of plating.

### Advantageous Effects of Invention

The present invention can provide a photosensitive element in which a high tackiness and a high resolution are realized, and a resist pattern formation method.

### BRIEF DESCRIPTION OF DRAWINGS

FIG. 1 is a cross-sectional view schematically illustrating one configuration example of a photosensitive element according to the present invention.

FIG. 2 is a view schematically illustrating the photosensitive element shown in FIG. 1, wherein actinic rays incident on a support film at the time of exposure are refracted until they reach a photosensitive resin layer.

### DESCRIPTION OF EMBODIMENTS

The embodiments of the present invention will be described in detail below.

Note that the numerical ranges indicated using “to” in the following descriptions also include the upper and lower limit values.

### Embodiment 1

### [Photosensitive Element]

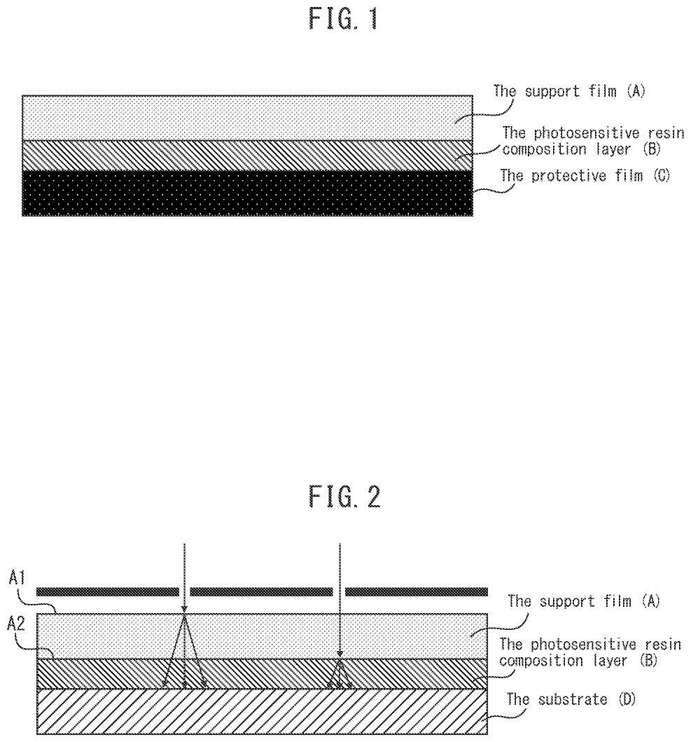

FIG. 1 is a cross-sectional view schematically illustrating one configuration example of the photosensitive element of the present invention.

The photosensitive element of the present invention comprises, in this order, a support film (A) and a photosensitive resin composition layer (B), wherein
a developed interfacial ratio Sdr_{A1}(%) of an interface (A1) of the support film (A) on an opposite side to that in contact with the photosensitive resin composition layer (B) as defined in ISO 25178 is:

Sdr_{A1}<0.005(%).

The photosensitive element of the present invention is further characterized by comprising, in this order, a support film (A) and a photosensitive resin composition layer (B), wherein
a developed interfacial ratio Sdr_{A2}(%) of an interface (A2) of the support film (A) on a side in contact with the photosensitive resin composition layer (B) and a developed interfacial ratio Sdr_{A1}(%) of an interface (A1) thereof on the opposite side as defined in ISO 25178 satisfy the following formula (1):

Sdr_{A1}/Sdr_{A2}<0.75 (1).

The photosensitive element of the present invention is further characterized by comprising, in this order, a support film (A) and a photosensitive resin composition layer (B), wherein
a surface particle number P_{A2} (particles) of 1.0 μm or more included in an area of 258 μm×260 μm of a surface (A2) of the support film (A) on a side in contact with the photosensitive resin composition layer (B) and a surface particle number P_{A1} (particles) of a surface (A1) thereof on the opposite side satisfy the following formula (2):

P_{A1}/P_{A2}<0.75 (2).

Note that as used herein, the surface particle number P is the number of particles of 1.0 μm or more contained in an area of 258 μm×260 μm of the support film (A) using a laser microscope.

The photosensitive element of the present invention is further characterized by comprising, in this order, a support film (A) and a photosensitive resin composition layer (B), wherein
a maximum surface particle size S_{A2} (μm) of a surface (A2) of the support film (A) on a side in contact with the photosensitive resin composition layer (B) and a maximum surface particle size S_{A1} (μm) of a surface (A1) thereof on the opposite side satisfy the following formula (3):

S_{A1}/S_{A2}<0.75 (3).

Note that as used herein, the maximum surface particle size S is a value measured using a laser microscope. If the particle is not a perfect sphere, the longest width of the particle is taken as the diameter of the particle.

The present inventors examined the influence of the surface shape of the support film (A) on the tackiness and resolution, and have discovered that in order to improve wrinkling of the sidewalls, i.e., to improve the straightness of the formed pattern, the surface roughness or surface particle number of a surface (coated surface) A2 of the support film (A) on a side where the photosensitive resin composition layer (B) is formed by application has substantially no influence, and the surface roughness or surface particle number of a surface (uncoated surface) A1 thereof on the opposite side is important.

The present inventors believe that this is because the light incident on the photosensitive resin layer (B) from the support film (A) has a lower refractive index than the light incident on the support film (A) from the air, and the present inventors presume that, as shown in FIG. 2, when the uncoated surface (A1) of the support film (A) has a large surface roughness, the incident light from the atmosphere to the support film (A) is greatly refracted (left arrow), and if the surface roughness of the uncoated surface (A1) is small, the incident light from the atmosphere to the support film (A) is substantially not refracted (right arrow), whereby a pattern with high mask reproducibility is formed, and sidewall wrinkling is reduced.

By reducing the surface roughness of the uncoated surface A1 of the support film (A), wrinkling of the sidewalls can be reduced, and high resolution can be realized. By increasing the surface roughness of the coated surface A2, the contact area between the support film (A) and the photosensitive resin layer (B) increases, whereby the anchoring effect increases, and high tackiness can be achieved.

Specifically, in the photosensitive element of the present invention, for the developed interfacial ratio Sdr of the support film (A), when uncoated surface (Sdr_{A1})<coated surface (Sdr_{A2}), for the surface particle number P of the support film (A), when uncoated surface (P_{A1})<coated surface (P_{A2}), or for the maximum surface particle size S of the support film (A), when uncoated surface (S_{A1})<coated surface (S_{A2}), high tackiness and high resolution can be realized.

Note that when the developed interfacial ratio Sdr, surface particle number P, or maximum surface particle size S of the support film (A) coated surface is large, due to the transfer thereof, the photosensitive resin layer (B) has increased surface unevenness, but this does not affect the resolution or straightness of the sidewalls.

Though it has conventionally been recognized that the coated surface (one side) should be smooth in order to improve the appearance of the resist shape or to prevent the unevenness caused by the surface roughness of the support film (A) from being transferred to the photosensitive resin layer, and in recent years, many support films (A) smoothed on only one side have been used in dry film applications, the smooth surface is used as a surface in contact with the photosensitive resin layer and the use thereof on the opposite side is unprecedented.

Specifically, according to the present invention, there can be provided a photosensitive element which achieves high tackiness and high resolution by the application thereof to a surface opposite to that normally used.

### <Support Film (A)>

The support film (A) according to the present embodiment is a layer or film for supporting the photosensitive resin composition layer (B), and is preferably a transparent substrate film which allows actinic rays emitted from the exposure light source to pass.

Examples of such support film include a polyethylene terephthalate film, polyvinyl alcohol film, polyvinyl chloride film, vinyl chloride copolymer film, polyvinylidene chloride film, vinylidene chloride copolymer film, polymethyl methacrylate copolymer film, polystyrene film, polyacrylonitrile film, styrene copolymer film, polyamide film, and cellulose derivative film. These films can also be used in a stretched form, as needed. The use of polyethylene terephthalate (PET) is conventionally preferable because of the moderate flexibility and strength thereof.

Among these, it is preferable to use a high-quality film having little internal foreign matter. Specifically, as the high-quality film, it is preferable to use a PET film synthesized using a Ge-based catalyst, a PET film synthesized using a Ti-based catalyst, a PET film having a small content of lubricant with a small diameter, a PET film containing lubricant only on one side of the film, a thin PET film, a PET film smoothed on at least one side, or a PET film roughened on at least one side by plasma treatment.

As a result, the photosensitive resin composition layer (B) can be irradiated with the exposure light without being blocked by internal foreign matter, whereby the resolution of the photosensitive element can be improved.

The number of particles having a diameter of 2 μm or more and 5 μm or less contained in the support film (A) as internal foreign matter is preferably 30 particles/30 mm² or less, more preferably 15 particles/30 mm² or less, and further preferably 10 particles/30 mm² or less.

The titanium element (Ti) content in the support film (A) is preferably 1 ppm or more and 20 ppm or less, more preferably 2 ppm or more and 12 ppm or less. When the titanium element content is 20 ppm or less, the amount of internal foreign matter derived from titanium element-containing aggregates can be reduced, whereby deterioration of the resolution can be prevented.

The film thickness of the support film (A) is preferably 5 μm or more and 16 μm or less, more preferably 6 μm or more and 12 μm or less. The thinner the support film, the smaller the amount of internal foreign matter, whereby reduction in resolution can be prevented, but when the film thickness is less than 5 μm, elongation deformation in the winding direction due to tension in coating and winding production processes, tearing due to minute scratches, or insufficient strength of the film may cause wrinkles during lamination.

It is preferable that at least one side of the support film (A) be subjected to a smoothing treatment using a calender device. As a result, the surface roughness of one side of the support film (A), particularly the surface A2 on a side which does not come into contact with the photosensitive resin composition layer (B) can be reduced, whereby the effect of the present invention can be enhanced.

From the viewpoint of improving the parallelism of light rays emitted to the photosensitive resin composition layer (B) and obtaining higher resolution after exposure development of the photosensitive element, the haze of the support film (A) is preferably 0.01% to 1.5%, more preferably 0.01% to 1.0%, and further preferably 0.01% to 0.5%.

In the photosensitive element of the present embodiment, the developed interfacial ratio Sdr_{A2}(%) of a surface (A2) of the support film (A) on a side in contact with the photosensitive resin composition layer (B) and the developed interfacial ratio Sdr_{A1}(%) of a surface (A1) thereof on the opposite side as defined in ISO 25178 satisfy the following formula (1):

Sdr_{A1}/Sdr_{A2}<0.75 (1).

In the photosensitive element, when uncoated surface (Sdr_{A1})<coated surface (Sdr_{A2}) regarding the developed interfacial ratio Sdr of the support film (A), high tackiness and high resolution are achieved.

A specific method for measuring the developed interfacial ratio Sdr is described in Examples, which are described later.

From the viewpoint of suitably exhibiting the effects of the present invention, Sdr_{A1}/Sdr_{A2} is preferably less than 0.60, more preferably less than 0.55, and further preferably less than 0.50. Sdr_{A1}/Sdr_{A2} may be greater than zero.

Sdr_{A1} and Sdr_{A2} are not particularly limited as long as they satisfy the above formula (1), and specifically, Sdr_{A1} is less than 0.005(%), preferably 0.0005% to 0.004%, more preferably to 0.003%, most preferably 0.0005% to 0.002%, and very highly preferably 0.0005% to Sdr_{A2} is preferably 0.006% to 0.03%, more preferably 0.006% to 0.02%, very preferably 0.006% to 0.01%, and very highly preferably 0.006% to 0.008%.

In the photosensitive element of the present embodiment, the surface particle number P_{A2} (particles) of 1.0 μm or more included in an area of 258 μm×260 μm of a surface (A2) of the support film (A) on a side in contact with the photosensitive resin composition layer (B) and a surface particle number P_{A1} (particles) of a surface (A1) thereof on the opposite side satisfy the following formula (2):

P_{A1}/P_{A2}<0.75 (2).

In the photosensitive element, when uncoated surface (P_{A1})<coated surface (P_{A2}) regarding the surface particle number P of the support film (A), high tackiness and high resolution can be achieved.

A specific method for measuring the surface particle number P is described in the Examples, which are described later.

P_{A1} and P_{A2} are not particularly limited as long as they satisfy the above formula (1). Specifically, P_{A1} is preferably 1 to 200, and more preferably 1 to 150. 1 to 100 is highly preferable, and 1 to 50 is very highly preferable.

P_{A2} is preferably 300 to 1500, more preferably 300 to 1000, very preferably 300 to 800, and very highly preferably 300 to 500.

Further, P_{A2}/P_{A1} is more preferably 0.001 to 0.5, very preferably 0.001 to 0.4, and very highly preferably 0.001 to 0.3.

In the photosensitive element of the present embodiment, the maximum surface particle size S_{A2} (μm) of a surface (A2) of the support film (A) on a side in contact with the photosensitive resin composition layer (B) and a maximum surface particle size S_{A1} (μm) of a surface (A1) thereof on the opposite side satisfy the following formula (3):

S_{A1}/S_{A2}<0.75 (3).

In the photosensitive element, when uncoated surface (S_{A1})<coated surface (S_{A2}) regarding the maximum surface particle size S of the support film (A), high tackiness and high resolution can be achieved.

From the viewpoint of suitably exhibiting the effects of the present invention, S_{A1}/S_{A2} is preferably less than 0.70, more preferably less than 0.60, and further preferably less than 0.58. S_{A1}/S_{A2} may be greater than zero.

A specific method for measuring the maximum surface particle size S is described in Examples, which are described later.

S_{A1} and S_{A2} are not particularly limited as long as they satisfy the above formula (3), and specifically, S_{A1} is preferably 0.01 μm to 1.0 μm, more preferably 0.01 μm to 0.5 μm, very preferably 0.01 μm to 0.3 μm, and very highly preferably 0.01 μm to 0.2 μm.

S_{A2} is preferably 1.0 μm to 10 μm, more preferably 1.0 μm to 8 μm, very preferably 1.0 μm to 5 μm, and very highly preferably 1.0 μm to 3 μm.

Note that when measuring any of the developed interfacial ratio Sdr, the surface particle number P, and the maximum surface particle size S of the support film (A), as long as there is a portion which satisfies any of the conditions of formulas (1) to (3) defined in the specific aspect of the present embodiment, such photosensitive element is included in the photosensitive element according to the specific aspect of the present embodiment. Specifically, even if a specified condition (any of formulas (1) to (3)) is not satisfied when measured at a certain point, such photosensitive element is included in the photosensitive element according to the particular aspect as long as it satisfies the specific conditions when measured at another location.

### <Photosensitive Resin Composition Layer (B)>

A photosensitive resin composition layer (B) is laminated onto the support film (A). A known photosensitive resin composition layer may be used as the photosensitive resin composition layer (B) according to the present embodiment. The photosensitive resin composition layer is conventionally formed from the following components: (i) an alkali-soluble polymer, (ii) an ethylenically unsaturated double bond-containing component (for example, an ethylenically unsaturated addition polymerizable monomer), and (iii) a photosensitive resin composition containing a photopolymerization initiator.

In the alkali-soluble polymer, which is component (i), from the viewpoint of alkali solubility, it preferably has a carboxyl group, and from the viewpoint of the strength of the cured film and the coatability of the photosensitive resin composition, it also preferably has an aromatic group in the side chain thereof.

In the photosensitive element of this embodiment, in the photosensitive resin layer (B), the comonomer ratio of (i) the structure having an aromatic ring of alkali-soluble polymer is preferably 50% or more, and more preferably 60% or more.

As described above, when the photosensitive resin layer (B) contains a large amount of the alkali-soluble polymer component having an aromatic ring, low tackiness tends to become a problem, whereby the effects of the present invention are enhanced. Styrene is preferable as the structure having an aromatic ring.

The acid equivalent of the alkali-soluble polymer is preferably 100 or more from the viewpoint of the development resistance of the photosensitive resin composition layer and the development resistance, resolution, and adhesion of the resist pattern, and from the viewpoint of developability and peelability of the photosensitive resin composition layer, it is preferably 600 or less, more preferably 250 to 550, and further preferably 300 to 500.

From the viewpoint of maintaining uniform thickness of the dry film resist and obtaining resistance to developer, the weight average molecular weight of the alkali-soluble polymer is preferably in the range of 5,000 to 500,000, more preferably 10,000 to 200,000, and further preferably 18,000 to 100,000. As used herein, the weight average molecular weight is the weight average molecular weight as measured by gel permeation chromatography (GPC) using a standard polystyrene calibration curve. The degree of dispersion of the alkali-soluble polymer is preferably 1.0 to 6.0.

Examples of alkali-soluble polymers include carboxylic acid-containing vinyl copolymers and carboxylic acid-containing cellulose.

The carboxylic acid-containing vinyl copolymer is a compound obtained by vinyl copolymerization of at least one first monomer selected from α,β-unsaturated carboxylic acids with at least one second monomer selected from alkyl (meth)acrylates, hydroxyalkyl (meth)acrylates, (meth)acrylamide and a compound obtained by substituting an alkyl group or an alkoxy group for the hydrogen on the nitrogen thereof, styrene and styrene derivatives, (meth)acrylonitrile, and glycidyl (meth)acrylate.

Examples of the first monomer used in the carboxylic acid-containing vinyl copolymer include acrylic acid, methacrylic acid, fumaric acid, cinnamic acid, crotonic acid, itaconic acid, and maleic acid half ester. These may be used alone or in combination of two or more thereof.

The content of the structural units of the first monomer in the carboxylic acid-containing vinyl copolymer is 15% by mass or more and 40% by mass or less, and preferably 20% by mass or more and 35% by mass or less, based on the mass of the copolymer. When the ratio is less than 15% by mass, development with an alkaline aqueous solution becomes difficult. When the ratio exceeds 40% by mass, the first monomer becomes insoluble in the solvent during polymerization, making it difficult to synthesize the copolymer.

Specific examples of the second monomer used in the carboxylic acid-containing vinyl copolymer include methyl (meth)acrylate, ethyl (meth)acrylate, n-propyl (meth)acrylate, cyclohexyl (meth)acrylate, n-butyl (meth)acrylate, 2-ethylhexyl (meth)acrylate, 2-hydroxyethyl (meth)acrylate, 2-hydroxypropyl (meth)acrylate, 4-hydroxybutyl (meth)acrylate, polyethylene glycol mono(meth)acrylate, polypropylene glycol mono(meth)acrylate, (meth)acrylamide, N-methylolacrylamide, N-butoxymethylacrylamide, styrene, α-methylstyrene, p-methylstyrene, p-chlorostyrene, (meth)acrylonitrile, and glycidyl (meth)acrylate, and these may be used alone or in combination of two or more thereof.

The content of the structural units of the second monomer in the carboxylic acid-containing vinyl copolymer is 60% by mass or more and 85% by mass or less, and preferably 65% by mass or more and 80% by mass or less, based on the mass of the copolymer.

From the viewpoint of introducing an aromatic group into the side chain, as the second monomer, it is more preferable to incorporate structural units of styrene or styrene derivatives such as α-methylstyrene, p-methylstyrene and p-chlorostyrene into the carboxylic acid-containing vinyl copolymer. In this case, the content ratio of the structural units of the styrene or styrene derivative in the carboxylic acid-containing vinyl copolymer is preferably 5% by mass or more and 35% by mass or less, and more preferably 15% by mass or more and 30% by mass or less based on the mass of the copolymer.

The weight average molecular weight of the carboxylic acid-containing vinyl copolymer is within the range of 10,000 to 200,000, and preferably within the range of 18,000 to 100,000. When this weight average molecular weight is less than 10,000, the strength of the cured film will be low. When the weight-average molecular weight exceeds 200,000, the viscosity of the photosensitive resin composition becomes excessively high, resulting in poor coatability.

The carboxylic acid-containing vinyl copolymer is preferably synthesized by adding a suitable amount of a radical polymerization initiator such as benzoyl peroxide or azoisobutyronitrile to a solution obtained by diluting a mixture of various monomers with a solvent such as acetone, methyl ethyl ketone, or isopropanol, followed by heating and stirring. In some cases, synthesis is performed while dropping a part of the mixture into the reaction solution. After completion of the reaction, a solvent may be further added to adjust the desired concentration. In addition to solution polymerization, bulk polymerization, suspension polymerization, and emulsion polymerization can also be used as synthesis means.

Examples of carboxylic acid-containing celluloses include cellulose acetate phthalate and hydroxyethyl/carboxymethyl cellulose. The content of the alkali-soluble polymer (A) is preferably in the range of 30% by mass to 80% by mass, and more preferably 40% by mass to 65% by mass, based on the total mass of the photosensitive resin composition. When this content is less than 30% by mass, the dispersibility in an alkaline developing solution is reduced, whereby the development time is significantly lengthened. When this content exceeds 80% by mass, the photo-curing of the photosensitive resin composition layer becomes insufficient, whereby the resistance as a resist decreases. The alkali-soluble polymers may be used alone or in combination of two or more thereof.

In the photosensitive element of the present embodiment, in the photosensitive resin layer (B), the comonomer ratio of the structure having an aromatic ring of alkali-soluble polymer is preferably 50% or more, and more preferably 60% or more.

As described above, when the photosensitive resin layer (B) contains a large amount of the alkali-soluble polymer component having an aromatic ring, low tackiness tends to become a problem, whereby the effects of the present invention are enhanced.

As the ethylenically unsaturated addition polymerizable monomer, which is (ii) component, known types of compounds can be used. Examples of the ethylenically unsaturated addition polymerizable monomer include 2-hydroxy-3-phenoxypropyl acrylate, phenoxytetraethylene glycol acrylate, β-hydroxypropyl-β′-(acryloyloxy)propyl phthalate, 1,4-tetramethylene glycol di(meth)acrylate, 1,6-hexanediol di(meth)acrylate, 1,4-cyclohexanediol di(meth)acrylate, heptapropylene glycol di(meth)acrylate, glycerol (meth)acrylate, 2-di(p-hydroxyphenyl)propane di(meth)acrylate, glycerol tri(meth)acrylate, trimethylolpropane tri(meth)acrylate, polyoxypropyl trimethylolpropane tri(meth)acrylate, poly oxyethyl trimethylolpropane tri(meth)acrylate, dipentaerythritol penta(meth)acrylate, dipentaerythritol hexa(meth)acrylate, trimethylolpropane triglycidyl ether tri(meth)acrylate, bisphenol A diglycidyl ether di(meth)acrylate, diallyl phthalate, polyethylene glycol di(meth)acrylate, polypropylene glycol di(meth)acrylate, 4-normal octylphenoxy pentapropylene glycol acrylate, bis(triethylene glycol methacrylate) nonapropylene glycol, bis(tetraethylene glycol methacrylate) polypropylene glycol, bis(triethylene glycol methacrylate) polypropylene glycol, bis(diethylene glycol acrylate) polypropylene glycol, 4-normal nonylphenoxyheptaethylene glycol dipropylene glycol (meth)acrylate, phenoxytetrapropylene glycol tetraethylene glycol (meth)acrylate, a compound containing an ethylene oxide chain in the molecule of a bisphenol A-based (meth)acrylic acid ester monomer, a compound containing a propylene oxide chain in the molecule of a bisphenol A-based (meth)acrylic acid ester monomer, and a compound containing both an ethylene oxide chain and a propylene oxide chain in the molecule of a bisphenol A-based (meth)acrylic acid ester monomer.

Furthermore, as the ethylenically unsaturated addition polymerizable monomer, a polyvalent isocyanate compound such as hexamethylene diisocyanate and toluylene diisocyanate or a urethane compound including hydroxyacrylate compounds such as 2-hy droxypropyl (meth)acrylate, oligoethylene glycol mono (meth)acrylate, and oligopropylene glycol mono (meth)acrylate can be used. These ethylenically unsaturated addition-polymerizable monomers may be used alone or in combination of two or more thereof.

The content of the ethylenically unsaturated addition polymerizable monomer is preferably 20% by mass or more and 70% by mass or less, and more preferably 30% by mass or more and 60% by mass or less, based on the total mass of the photosensitive resin composition. If the content is less than 20% by mass, the curing of the photosensitive resin is insufficient, whereby the strength of the resist is insufficient. Conversely, if this content exceeds 70% by mass, when the photosensitive element is stored in a rolled form, a phenomenon in which the photosensitive resin composition layer or the photosensitive resin composition gradually protrudes from the end face of the roll, i.e., edge fusion, becomes more likely to occur.

Examples of the photopolymerization initiator, which is component (iii), include aromatic ketones such as benzyl dimethyl ketal, benzyl diethyl ketal, benzyl dipropyl ketal, benzyl diphenyl ketal, benzoin methyl ether, benzoin ethyl ether, benzoin propyl ether, benzoin phenyl ether, thioxanthone, 2,4-dimethylthioxanthone, 2,4-diethylthioxanthone, 2-isopropylthioxanthone, 4-isopropylthioxanthone, 2,4-diisopropylthioxanthone, 2-fluorothioxanthone, 4-fluorothioxanthone, 2-chlorothioxanthone, 4-chlorothioxanthone, 1-chloro-4-propoxythioxanthone, benzophenone, 4,4′-bis(dimethylamino)benzophenone (Michler's ketone), 4,4′-bis(diethylamino)benzophenone, and 2,2-dimethoxy-2-phenylacetophenone; biimidazole compounds such as 2-(o-chlorophenyl)-4,5-diphenylimidazolyl dimer; acridines such as 9-phenylacridine; anthracenes such as 9,10-diethoxyanthracene, 9,10-dibutoxyanthracene, and 9,10-diphenylanthracene; aromatic initiators such as α,α-dimethoxy-α-morpholino-methylthiophenylacetophenone and 2,4,6-trimethylbenzoyldiphenylphosphine oxide; N-aryl amino acids such as phenylglycine and N-phenylglycine; oxime esters such as 1-phenyl-1,2-propanedione-2-o-benzoyloxime, and ethyl 2,3-dioxo-3-phenylpropionate-2-(o-benzoylcarbonyl)-oxime; as well as p-dimethylaminobenzoic acid, p-diethylaminobenzoic acid and p-diisopropylaminobenzoic acid and esters thereof with alcohols, and p-hydroxybenzoic acid esters. Among these, a combination of 2-(o-chlorophenyl)-4,5-diphenylimidazolyl dimer and Michler's ketone or 4,4′-(diethylamino)benzophenone is preferable.

The content of the photopolymerization initiator is preferably 0.01% by mass or more and 20% by mass or less, and more preferably 1% by mass or more and 10% by mass or less, based on the total mass of the photosensitive resin composition. When this content is less than 0.01% by mass, the sensitivity is insufficient. When this content exceeds 20% by mass, the ultraviolet absorption rate increases, whereby hardening of the bottom portion of the photosensitive resin composition layer becomes insufficient.

In order to improve the thermal stability and/or storage stability of the photosensitive resin composition layer (B) according to the present embodiment, it is preferable that the photosensitive resin composition or the photosensitive resin composition layer contain a radical polymerization inhibitor. Examples of the radical polymerization inhibitor include p-methoxyphenol, hydroquinone, pyrogallol, naphthylamine, t-butylcatechol, cuprous chloride, 2,6-di-t-butyl-p-cresol, 2,2′methylenebis(4-ethyl-6-t-butylphenol), and 2,2′-methylenebis(4-methyl-6-t-butylphenol).

In the present embodiment, the photosensitive resin composition layer (B) may contain a coloring substance such as a dye or pigment. Examples of the coloring substance include fuchsine, phthalocyanine green, auramine base, chalcoxide green S, paramagenta, crystal violet, methyl orange, nile blue 2B, victoria blue, malachite green, basic blue 20, and diamond green.

In the present embodiment, the photosensitive resin composition layer (B) may contain a color-developing dye which develops color when irradiated with light. As the color-developing dye, for example, a combination of a leuco dye and a halogen compound is known. Examples of the leuco dye include tris(4-dimethylamino-2-methylphenyl)methane (Leucocrystal violet) and tris(4-dimethylamino-2-methylphenyl)methane (Leucomalachite green). Examples of the halogen compound include amyl bromide, isoamyl bromide, isobutylene bromide, ethylene bromide, diphenylmethyl bromide, benzal bromide, methylene bromide, tribromomethylphenyl sulfone, carbon tetrabromide, tris(2,3-dibromopropyl) phosphate, trichloroacetamide, amyl iodide, isobutyl iodide, 1,1,1-trichloro-2,2-bis(p-chlorophenyl)ethane, and hexachloroethane.

In the present embodiment, the photosensitive resin composition layer (B) may contain additives such as a plasticizer, as needed. Examples of additives include phthalates such as diethyl phthalate, o-toluenesulfonamide, p-toluenesulfonamide, tributyl citrate, triethyl citrate, acetyl triethyl citrate, acetyl citrate tri-n-propyl, acetyl citrate tri-n-butyl, polypropylene glycol, polyethylene glycol, polyethylene glycol alkyl ether, and polypropylene glycol alkyl ether.

The thickness of the photosensitive resin composition layer (B) is preferably 3 to 400 μm, and the more preferably the upper limit is 300, 200, 100, or 50 μm. As the thickness of the photosensitive resin layer approaches 3 μm, the resolution improves, and as the thickness approaches 400 μm, the film strength improves. The thickness can appropriately be selected in accordance with the application.

### <Protective Film (C)>

The protective film (C) is laminated on the photosensitive resin composition layer (B) side of the support film (A) and the photosensitive resin composition layer (B) laminate, and functions as a cover.

The protective film (C) can easily be peeled because the adhesive strength of the protective film (C) with the photosensitive resin composition layer (B) is sufficiently smaller than that of the support film (A). For example, a polyethylene film, a polypropylene film, an oriented polypropylene film, a polyester film, or the like can preferably be used as the protective film (C), and it more preferable that at least the surface of the protective film (C) be composed of a polypropylene resin.

The film thickness of the protective film (C) is preferably 10 to 100 μm, and more preferably 10 to 50 μm. Examples thereof include EM-501, E-200, E-201F, FG-201, and MA-411 manufactured by Oji F-Tex Co., Ltd., KW37, 2578, 2548, 2500, and YM17S manufactured by Toray Industries, Inc., and GF-18, GF-818, and GF-858 manufactured by Tamapoly Co., Ltd.

### <Resist Pattern Formation Method>

A resist pattern formation method using the photosensitive element according to the present embodiment preferably comprises, in this order, the following steps:
a lamination step of laminating the photosensitive element on a substrate,
an exposure step of exposing a photosensitive resin layer of the photosensitive element, and
a development step of removing an unexposed part of the photosensitive resin layer by development.

In the lamination step, specifically, after peeling the protective film (C) from the photosensitive element, the photosensitive resin composition layer is heat-pressed onto the surface of a support (for example, a substrate) using a laminator to laminate once or multiple times.

Examples of the material of the substrate include copper, stainless steel (SUS), glass, and indium tin oxide (ITO). The heating temperature during lamination is generally 40° C. to 160° C. Heat crimping can be performed using a two-stage laminator with a series of two rollers or by passing the laminate of the substrate and the photosensitive resin composition layer through rollers multiple times.

In the exposure step, the photosensitive resin layer is exposed to actinic rays using an exposure machine. Exposing can be performed after peeling of the support if desired. When exposing through a photomask, the amount of exposure is determined by the illuminance of the light source and the exposure time, and may be measured using a photometer. Direct imaging exposure may be performed in the exposure step. In direct imaging exposure, the image is exposed directly on the substrate by a drawing device without using a photomask. As the light source, a semiconductor laser or an ultra-high pressure mercury lamp having a wavelength of 350 nm to 410 nm can be used, and it is preferable to use a light source having a wavelength of 405 nm or less. When the drawing pattern is controlled by a computer, the exposure amount is determined by the illuminance of the exposure light source and the movement speed of the substrate.

The light irradiation method used in the exposure step is preferably at least one method selected from the projection exposure method, proximity exposure method, contact exposure method, direct imaging exposure method, and electron beam direct drawing method, and it is more preferable exposure be carried out by the projection exposure method. In order to improve adhesion, heating may be performed after exposure, and in the heating step, the exposed photosensitive resin is heated (heating after exposure). The heating temperature is preferably 30° C. to 150° C., and more preferably 60° C. to 120° C. By performing this heating step, resolution and adhesion are improved. As the heating means, hot air, infrared rays, far infrared rays, a constant temperature bath, a hot plate, a hot air dryer, an infrared dryer, or hot roller can be used.

Hot roller is preferable as the heating means because the treatment can be performed in a short time, and a series of two or more hot rollers is more preferable. The elapsed time from exposure to heating, more strictly, the elapsed time from the time the exposure is stopped to the time heating is started is preferably within 15 minutes or within 10 minutes. The elapsed time from the time when exposure is stopped to the time when temperature rise is started may be 10 seconds or more, seconds or more, 30 seconds or more, 1 minute or more, 2 minutes or more, 3 minutes or more, 4 minutes or more, or 5 minutes or more.

In the development step, the unexposed part or exposed part in the exposed photosensitive resin composition layer is removed with a developer using a developing device. If there is a support film on the photosensitive resin composition layer after exposure, this is removed. Next, the unexposed part or the exposed part is developed and removed using a developer consisting of an alkaline aqueous solution to obtain a resist image.

As the alkaline aqueous solution, aqueous solutions such as Na₂CO₃ and K₂CO₃ are preferable. Though the alkaline aqueous solution is selected in accordance with the characteristics of the photosensitive resin composition layer, an Na₂CO₃ aqueous solution having a concentration of 0.2% to 2% by weight is generally used. The alkaline aqueous solution may be mixed with a surfactant, an antifoaming agent, and a small amount of an organic solvent for promoting development. The temperature of the developer in the development step is preferably maintained constant within the range of 20° C. to 40° C.

Though a resist pattern can be obtained by the above steps, if desired, a heating step at 60° C. to 300° C. can also be performed. By performing this heating step, the chemical resistance of the resist pattern can be improved. A heating furnace which uses hot air, infrared rays, or far infrared rays can be used in the heating step.

### <Conductor Pattern (Plating Pattern) Formation Method>

In order to obtain a conductor pattern, a conductor pattern formation step of etching or plating the substrate on which the resist pattern is formed may be performed after the development step or the heating step.

The conductor pattern is produced using, for example, a metal plate or a metal film insulating plate as a substrate, forming a resist pattern by the resist pattern formation method described above, and thereafter performing a conductor pattern formation step. In the conductor pattern formation step, a known etching method or plating method is used to form a conductor pattern on the substrate surface (for example, copper surface) exposed by development.

In one aspect, a conductor pattern (plating pattern) can be formed using the photosensitive element. In one aspect, the photosensitive element can be laminated on a copper substrate having a copper shield layer having a thickness t (um). The copper substrate has, for example, a copper shield layer on the surface thereof.

Further, in an aspect, in the plating pattern formation method:
when the photosensitive element laminated on the copper substrate is subjected to:
(1) exposure using an exposure mask having exposed and unexposed parts having a pitch of X (μm), and
(2) formation of lines/spaces of a photosensitive resin layer by development after the exposure, and
an average space width D_{W1} is {(±10% of (X/2))+t} or more, and when
(3) formation of a plating pattern by plate processing of the spaces, and
(4) peeling of the photosensitive resin layer from the substrate, are carried out,
an average pattern width P_{W1} of plating is within ±10% of the average space width D_{W1}.

The copper substrate is, for example, an electroless copper plating substrate formed on an insulating film having a copper shield layer of thickness t (um).

The pitch X of the exposure mask used in (1) exposure described above is a repeating unit of a set of an exposed part and an unexposed part. Thus, when the lengths of the exposed part and the unexposed part are substantially the same, the widths of the exposed part and the unexposed part are each approximately (X/2). Considering an error of approximately ±10%, and considering future etching of the copper shield layer (thickness t um), it is preferable that the (2) average space width D_{W1} after development described above be {((X/2)±10%)+t} or more.

Thereafter, the average pattern width P_{W1} of plating obtained through the (3) and (4) described above is within ±10% of the average space width D_{W1} after development. When plating the spaces in the lines/the spaces of the photosensitive resin layer, the space width and the plating pattern width are theoretically the same. Conversely, since the plating pattern presses the lines of the photosensitive resin layer during plating, or the lines of the photosensitive resin layer temporarily swell during plating and thereby narrow the spaces, the average pattern width P_{W1} of plating may increase or decrease relative to the average space width D_{W1}. In this case, it is preferable to control the average pattern width P_{W1} of plating within ±10% of the average space width D_{W1}. Such control can be easily realized by using the photosensitive element.

The average space width D_{W1} t and the average pattern width P_{W1} of plating can be obtained, for example, by selecting a plurality of arbitrary locations (e.g., 50 locations, 30 locations, or 20 locations) on an image captured with an optical microscope and calculating the average width of the plurality of locations.

The plating in (3) described above is, for example, electrolytic copper plating. In one aspect, electroplating can be carried out by immersing the substrate in which the lines/spaces (e.g., L/S=5/5) of the photosensitive resin layer are formed in a mixed solution of copper sulfate, sulfuric acid, or concentrated hydrochloric acid. The electroplating conditions include, for example, a bath temperature of 25° C., a current density of 1.0 A/dm 2, and a plating time of 20 minutes.

The copper thickness can be confirmed with a known thickness meter. After electroplating, in (4), the dry film can be peeled with an aqueous solution having stronger alkalinity than the developer, such as a 3% sodium hydroxide solution at 50° C. Though the alkaline aqueous solution for peeling (hereinafter also referred to as the “peeling solution”) is not particularly limited, an aqueous solution of NaOH or KOH having a concentration of 2% to 5% by weight, or an organic amine-based peel liquid is generally used. A small amount of water-soluble solvent may be added to the peeling solution. Examples of water-soluble solvents include alcohols. The temperature of the peeling solution in the peeling step is preferably within the range of 40° C. to 70° C.

In an aspect, in a wiring pattern formation method, when, after (4) described above,
(5) formation of a post-etch plating pattern, which remains after etching of the copper shield layer on the substrate after the peeling of the plating pattern, of the plating pattern is carried out,
an average pattern width F_{W1} t of post-etch plating is less than the average pattern width P_{W1} of plating.

Specifically, though the average pattern width P_{W1} of plating is reduced due to etching of the copper shield layer, the average pattern width F_{W1} t of post-etch plating can be designed in anticipation of such reduction. As a result, the ultimately obtained average pattern width F_{W1} t of post-etch plating becomes more accurate. Such a method can be easily realized using the photosensitive element described above.

The average pattern width P_{W1} of plating can be obtained, for example, by selecting a plurality of arbitrary locations (for example, 50 locations, 30 locations, or 20 locations) on an image captured with an optical microscope and calculating the average width of the plurality of locations

In the (5) etching (flash etching) described above, the copper shield layer can be removed with a predetermined etching solution. Examples of the etching solution include, but are not limited to, a mixed etching solution of sulfuric acid and hydrogen peroxide (manufactured by Ebara Densan Co., Ltd.).

In the present embodiment, the photosensitive element or roll thereof can be used in the production of printed wiring boards; the production of lead frames for mounting IC chips; metal foil precision processing such as metal mask production; the production of packages such as Ball Grid Arrays (BGA) and Chip Size Packages (CSP); the production of tape substrates such as Chip on Film (COF) and Tape Automated Bonding (TAB); the production of semiconductor bumps; and the production of barrier ribs for flat panel displays such as ITO electrodes, address electrodes, and electromagnetic wave shields.

Note that unless otherwise specified, the values of the respective parameters described above are measured according to the measurement method of the Examples, which are described later.

### Embodiment 2

In an aspect, the photosensitive element can be laminated on a copper substrate having a copper shield layer having an average thickness of 1 um or less, and
when the photosensitive element laminated on the copper substrate is subjected to:
(1) exposure using an exposure mask having exposed and unexposed parts with a pitch of 10 μm, and
(2) formation of lines/spaces of a photosensitive resin layer by development after the exposure, the average space width D_{W1} and the minimum space width D_{W2} satisfy the relationship:

1.00<D_{W1}/D_{W2}<1.10.

Photosensitive elements which satisfy such a relationship have less wrinkling of the side walls of the photosensitive resin pattern, whereby a highly accurate wiring pattern can easily be produced.

From the same point of view as above, D_{W1}/D_{W2} is preferably 1.09 or less, and more preferably 1.08 or less.

In this photosensitive element, the photosensitive element described in Embodiment 1 can be used, and according to this, the above relationship can be easily realized.

Furthermore, in an aspect, the photosensitive element can be laminated on a copper substrate having a copper shield layer having an average thickness of 1 um or less, and when:
(1) exposure using an exposure mask having exposed and unexposed parts with a pitch of 10 μm,
(2) formation of lines/spaces of a photosensitive resin layer by development after the exposure,
(3) formation of a plating pattern by plate processing of the spaces, and
(4) peeling of the photosensitive resin layer from the substrate, are carried out,
the average pattern width P_{W1} of plating and the plating minimum pattern width P_{W2} satisfy the relationship:

1.00<P_{W1}/P_{W2}<1.10.

Photosensitive elements which satisfy such a relationship have less wrinkling of the side walls of the plating pattern, whereby a highly accurate wiring pattern can easily be produced.

From the same point of view as above, P_{W1}/P_{W2} is preferably 1.09 or less, and more preferably 1.08 or less.

In this photosensitive element, the photosensitive element described in Embodiment 1 can be used, and according to this, the above relationship can be easily realized.

Further, in an aspect, the photosensitive element can be laminated on a copper substrate having a copper shield layer having an average thickness of 1 um or less, and when:
(1) exposure using an exposure mask having exposed and unexposed parts with a pitch of 10 μm,
(2) formation of lines/spaces of a photosensitive resin layer by development after the exposure,
(3) formation of a plating pattern by plate processing of the spaces,
(4) peeling of the photosensitive resin layer from the substrate, and
(5) formation of a post-etch plating pattern, which remains after etching of the copper shield layer on the substrate after the peeling of the plating pattern, of the plating pattern, are carried out,
the average pattern width F_{W1} of post-etch plating and the minimum pattern width F_{W2} of post-etch plating satisfy the relationship:

1.00<F_{W1}/F_{W2}<1.10.

Photosensitive elements which satisfy such a relationship have less wrinkling of the side walls of the etched plating pattern, whereby a highly accurate wiring pattern can easily be produced.

From the same point of view as above, F_{W1}/F_{W2} is preferably 1.09 or less, and more preferably 1.08 or less.

In this photosensitive element, the photosensitive element described in Embodiment 1 can be used, and according to this, the above relationship can be easily realized.

The photosensitive element according to the present embodiment can also obtain the effects obtained by the photosensitive element according to the first embodiment, and as described above, a highly accurate wiring pattern can easily be produced.

### EXAMPLES

Next, the present embodiment will more specifically be described by way of Examples and Comparative Examples. However, the present embodiment is not limited to the following Examples unless they deviate from the spirit thereof

Evaluations samples were produced as follows.

### <Production of Photosensitive Element>

The components (the number of each component indicates the compounding amount (parts by mass) as a solid content) shown in Table 1 below and methyl ethyl ketone weighed so as to achieve a solid concentration of 55% were sufficiently stirred and mixed to obtain a photosensitive resin composition preparation. The details of the components shown in Table 1 are shown in Table 2.

As the support film (A), the polyethylene terephthalate (PET) films having a width of 300 mm and different surface shapes shown in Tables 3 to 5 below were used. For the PET films, materials in which the type of added particles, size, concentration, and particle size distribution were adjusted were used, and arbitrary surfaces were subjected to coating treatment or plasma treatment. The details of the films shown in Tables 3 to 5 are shown in Table 6.

A solution of the photosensitive resin composition formulation shown in Tables 1 and 2 was applied was applied to the surface of the support film (A) and dried with hot air at 90° C. for 1.5 minutes to form the photosensitive resin composition layer (B) was formed. At that time, the thickness of the photosensitive resin composition layer (B) after heating was adjusted to 15 μm. A protective film (C) was laminated onto the surface of the photosensitive resin composition layer on the side on which the support film (A) was not laminated to obtain a photosensitive element.

### <Substrate>

As an image quality evaluation substrate, S'PERFLEX (manufactured by Sumitomo Metal Mining Co., Ltd.) produced by the sputtering copper plating method was used.

As a plating evaluation substrate, a substrate in which a copper-clad laminate was laminated with ABF-GX92 (manufactured by Ajinomoto Finetech Co., Ltd.) as an insulating film, and then subjected to desmearing and electroless copper plating (copper seed layer with a thickness of 1 lam) was used. The substrate surface roughness was adjusted to Ra=0.4 to 0.3 μm by adjusting the swelling temperature in the desmear process.

### <Lamination>

While peeling the protective film (C) of the photosensitive element, the photosensitive element was laminated onto the evaluation substrate which was preheated to 50° C. using a hot roll laminator (AL-700, manufactured by Asahi Kasei Co., Ltd.) at a roll temperature of 105° C. The air pressure was 0.35 MPa and the lamination speed was 1.5 m/min.

### <Exposure>

Two hours after lamination, the surface side of the support film of the photosensitive element laminate body was exposed with monochromatic i-line (365 nm) light using a split projection exposure device (UX2003 SM-MSO4 manufactured by Ushio Inc., using an i-line bandpass filter). A chrome glass photomask having a line/space (L/S)=7/7, L/S=5/5 design was used, and each photosensitive element was exposed with the amount of exposure that yielded the minimum resolution.

In Example 7, exposure was performed using exposure data including the pattern of L/S=7/7 by means of a direct imaging exposure device (Orbotech Co., Ltd., Paragon-Ultra 100, light source peak wavelength: 355 nm) at an exposure amount that yielded the minimum resolution.

In Example 8, exposure was performed using exposure data including the pattern of L/S=7/7 by means of a direct imaging exposure device (ADTEC Engineering IP-8 M8000H, light source peak wavelength: 405 nm) at an exposure amount that yielded the minimum resolution.

In Example 9, exposure was performed using a chrome glass photomask having a design of L/S=7/7, L/S=5/5 by means of an exposure device (Parallel light expose machine (parallel light EXM-1201 manufactured by Oak Manufacturing Co., Ltd.)) having an ultra-high pressure mercury lamp at an exposure amount that yielded the minimum resolution.

### <PEB: Post Exposure Bake>

The exposed substrate was heated in a hot air oven preheated to 60° C. for 1 minute.

### <Development>

After peeling the support film (A) of the photosensitive element laminate, development was carried out using an alkali developing machine (dry film developing machine manufactured by Fuji Kiko Co., Ltd.) by spraying a 1 mass % Na₂CO₃ aqueous solution at 30° C. for a predetermined period of time. The development spray time was twice the shortest development time, and the washing spray time after development was twice the shortest development time. At this time, the shortest time required for the photosensitive resin layer of the unexposed part to completely dissolve was taken as the shortest development time.

TABLE 1

| Compound | Composition 1 | Composition 2 | Composition 3 | Composition 4 | Composition 5 |
|---|---|---|---|---|---|
| A-1 | 57 | | 57 | | |
| A-2 | | 57 | | 57 | |
| A-3 | | | | | 57 |
| B-1 | 17 | 15 | 20 | 15 | 20 |
| B-2 | 6 | 8 | 6 | 6 | 6 |
| B-3 | 11 | 11 | 7 | 14 | 9 |
| B-4 | 5 | 5 | 5 | 5 | 5 |
| C-1 | 3 | 3 | 3 | 3 | 3 |
| C-2 | | 0.1 | | | |
| C-3 | | | 0.1 | | |
| C-4 | 0.1 | | | 0.1 | 0.1 |
| D-1 | 0.2 | 0.2 | 0.2 | 0.2 | 0.2 |
| D-2 | 0.3 | 0.3 | 0.3 | 0.3 | 0.3 |
| Total | 99.1 | 99.1 | 98.1 | 100.1 | 100.1 |

TABLE 2

| Number | Structure |
|---|---|
| A-1 | Methacrylic acid/methyl methacrylate/styrene/n-butyl acrylate = 25/10/60/5, |
| | Mw = 28.000 in 54% acetone solution |
| A-2 | Methacrylic acid/styrene/benzyl methacrylate = 25/60/15, Mw = |
| | 19,000 in 54% acetone solution |
| A-3 | Methacrylic acid/cyclohexyl methacrylate/benzyl acrylate = 22/50/28, Mw = |
| | 30,000 in 54% acetone solution |
| B-1 | Tetramethacrylate obtained by adding an average of 15 mol of ethylenic oxide |
| | to benzoylethritol |
| B-2 | Dimethacrylate of polyethylene glycol having an average of 2 mol of ethylene |
| | oxide attached to each end of bisphenol A |
| B-3 | Dimethacrylate of poly(ethylene glycol) having an average of 1 mol of ethylene |
| | oxide added to each end of bisphenol A |
| B-4 | Dimethacrylate of polyphenylene glycol (12 mol of repeating units of |
| | polyphenylene glycol) |
| C-1 | 2-(o-chlorophenyl)-4,5-diphenylimidazole dimer |
| C-2 | 9,10-diphnilanthracene |
| C-3 | 9,10-bis(isopropoxycarbonylmethoxy) anthracene, (manufactured by Kawasaki Kasei |
| | Kogyo Co., Ltd., Anthracure-UVS-107) |
| C-4 | 4,4-bis(diethylamino)benzophenone |
| D-1 | Diamond green |
| D-2 | Leucocrystal violet |

Evaluation of the obtained samples was performed as follows.

### <Surface Particle Number P>

The average value of the number of surface particles of 1.0 μm or more per 4 measurement repetitions among particles extracted from a field of view of 258 μm×260 μm using a laser microscope (OLS4100 manufactured by Olympus) under the following settings was calculated for an arbitrary surface of the support film (A) peeled from the produced photoelectric element.
Measurement conditions: Objective lens 50×
Measuring range: 258 μm×260 μm
Measurement mode: particle analysis (threshold: 13%, small particle removal: 5, hole filling:

### <Maximum Surface Particle Size S>

The average value of the maximum surface particle size per 4 measurement repetitions among particles extracted from a field of view of 258 μm×260 μm using a laser microscope (OLS4100 manufactured by Olympus) under the following settings was calculated for an arbitrary surface of the support film (A) peeled from the produced photoelectric element.
Measurement conditions: Objective lens 50×
Measuring range: 258 μm×260 μm
Measurement mode: particle analysis (threshold: 13%, small particle removal: 5, hole filling: 20)

### <Developed Interfacial Ratio Sdr>

The surface roughness of an arbitrary surface of the support film (A) peeled from the produced photosensitive element using a scanning white light interference microscope (VS1800 made by Hitachi High-Tech) based on the method specified in ISO 25178.
Measurement conditions: objective lens 50×, intermediate lens 1×, camera high pixel
Measuring range: 112 μm×112 μm
Measurement mode: WAVE
Surface correction: quaternary surface correction

### <Film Adhesive Strength>

In a sample which was subjected to humidity conditioning (23° C., 50% RT) for one day after the photosensitive element was laminated on a 1.2 mmt copper-clad laminate, the support film (A) was peeled from the photosensitive resin layer (B) in the direction of 180° at a tensile speed of 100 mm/min using Tensilon in a test method based on JIS Z 0237:2009, and the average value excluding the maximum and minimum values of the five measurements was judged according to the following criteria.
Acceptable: maximum average of 4.0 gf or more
Unacceptable: maximum average of less than 4.0 gf

### <Resist Side Protrusion Number>

The number of protrusions and splinters (0.4 μm or more) on the side surface of the resist in a theoretical L/S=7/7 developed resist pattern in a field of view of 90 μm×70 μm was counted using a scanning electron microscope (Hitachi High-Tech S-3400) and evaluated according to the following criteria.
Excellent: 0 to 10
Good: 10 to 100
OK: 100 to 300
Poor: 300 or more

### <Electrolytic Copper Plating>

The developed substrate on which a L/S=5/5 was formed was immersed in an electrolytic copper plating bath (copper sulfate: 70 g/L, sulfuric acid: 270 g/L, concentrated hydrochloric acid: 50 ppm, trace amounts of additives), and electrolytic plating was performed for 20 minutes at a bath temperature of 25° C. and a current density of 1.0 A/dm². As a result, a plating pattern was formed. It was confirmed with a thickness gauge that the plated copper had a thickness of 12 μm, and the dry film was peeled from the substrate with a 3% sodium hydroxide solution at 50° C.

### <Flash Etching>

The copper shield layer (1 μm thickness) was removed by flash etching with a mixed etching solution of sulfuric acid/hydrogen peroxide (manufactured by Ebara Densan Co., Ltd.). As a result, an etched plating pattern was formed.

### <Space/Pattern Width Measurement>

The developed resist pattern (theoretically L/S=5/5) was measured at 50 arbitrary points using an optical microscope (Nikon Lv100Nd) in a field of view of 90 μm×70 μm, and the average space width D_{W1} and the minimum space width D_{W2} were calculated.

The plating pattern (theoretically L/S=5/5) obtained by peeling the dry film after electrolytic copper plating was used to calculate the average pattern width P_{W1} of plating and the plating minimum pattern width P_{W2} in the same manner.

The etched plating pattern (theoretically L/S=4/6) after flash etching was calculated by the same measurement method to calculate the average pattern width F_{W1} of post-etch plating and the minimum pattern width F_{W2} of post-etch plating.

The evaluation results are shown in the following Tables.

TABLE 3

| | Ex 1 | Ex 2 | Ex 3 | Ex 4 | Ex 5 | Ex 6 |
|---|---|---|---|---|---|---|
| Film name | PET-6 | PET-1 | PET-2 | PET-3 | PET-4 | 16QS68 |
| Support film thickness [μm] | 16 | 16 | 16 | 12 | 16 | 16 |
| Composition | 1 | 1 | 1 | 1 | 1 | 1 |
| Photosensitive resin composition | 15 | 15 | 15 | 15 | 15 | 15 |
| layer thickness [μm] | | | | | | |
| Exposure method | Pro- | Pro- | Pro- | Pro- | Pro- | Pro- |
| | jection | jection | jection | jection | jection | jection |
| Exposure wavelength | i-line | i-line | i-line | i-line | i-line | i-line |
| Surface particle number P | 0.04 | 0.13 | 0.12 | 0.18 | 0.19 | 0.14 |
| (P_{A1}/P_{A2}) | | | | | | |
| Surface particle size S | 0.06 | 0.33 | 0.38 | 0.50 | 0.57 | 0.50 |
| (S_{A1}/S_{A2}) | | | | | | |
| Developed interfacial ratio Sdr | 0.25 | 0.14 | 0.20 | 0.20 | 0.25 | 0.26 |
| (Sdr_{A1}/Sdr_{A2}) | | | | | | |
| Developed interfacial ratio | 0.0006 | 0.001 | 0.0013 | 0.0013 | 0.0016 | 0.002 |
| Sdr_{A1} [%] | | | | | | |
| Support adhesive strength | Ac- | Ac- | Ac- | Ac- | Ac- | Ac- |
| | ceptable | ceptable | ceptable | ceptable | ceptable | ceptable |
| Resist side surface | Excel- | Excel- | Excel- | Excel- | Good | Excel- |
| protrusion number | lent | lent | lent | lent | | lent |
| Avg space width D_{W1}/ | 1.02 | 1.03 | 1.06 | 1.06 | 1.08 | 1.06 |
| Min space width D_{W2} | | | | | | |
| Avg pattern width P_{W1} | 1.02 | 1.03 | 1.06 | 1.06 | 1.08 | 1.06 |
| of plating/min pattern width | | | | | | |
| P_{W2} of plating | | | | | | |
| Avg pattern width F_{W1} | 1.02 | 1.03 | 1.07 | 1.07 | 1.09 | 1.07 |
| of post-etch plating/min pattern width | | | | | | |
| F_{W2} of post-etch plating | | | | | | |

TABLE 4

| | Ex 7 | Ex 8 | Ex 9 | Ex 10 | Ex 11 | Ex 12 | Ex 13 | Ex 14 |
|---|---|---|---|---|---|---|---|---|
| Film name | PET-2 | PET-2 | PET-2 | PET-2 | PET-2 | PET-2 | PET-2 | PET-5 |
| Support film thickness [μm] | 16 | 16 | 16 | 16 | 16 | 16 | 16 | 16 |
| Composition | 1 | 1 | 1 | 2 | 3 | 4 | 5 | 1 |
| Photosensitive resin composition | 15 | 15 | 15 | 15 | 15 | 15 | 15 | 15 |
| layer thickness [μm] | | | | | | | | |
| Exposure method | DI | DI | Parallel | Pro- | Pro- | Pro- | Pro- | Pro- |
| | | | light | jection | jection | jection | jection | jection |
| Exposure wavelength | i-line | h-line | ghi-line | i-line | i-line | i-line | i-line | i-line |
| Surface particle number P | 0.12 | 0.12 | 0.12 | 0.12 | 0.12 | 0.12 | 0.12 | 23.00 |
| (P_{A1}/P_{A2}) | | | | | | | | |
| Surface particle size S | 0.38 | 0.38 | 0.38 | 0.38 | 0.38 | 0.38 | 0.38 | 17.50 |
| (S_{A1}/S_{A2}) | | | | | | | | |
| Developed interfacial ratio Sdr | 0.14 | 0.14 | 0.14 | 0.14 | 0.14 | 0.14 | 0.14 | 4.00 |
| (Sdr_{A1}/Sdr_{A2}) | | | | | | | | |
| Developed interfacial ratio | 0.001 | 0.001 | 0.001 | 0.001 | 0.001 | 0.001 | 0.001 | 0.0024 |
| Sdr_{A1} [%] | | | | | | | | |
| Support adhesive strength | Ac- | Ac- | Ac- | Ac- | Ac- | Ac- | Ac- | Unac- |
| | ceptable | ceptable | ceptable | ceptable | ceptable | ceptable | ceptable | ceptable |
| Resist side surface | Good | Ac- | Ac- | Excel- | Excel- | Excel- | Excel- | Good |
| protrusion number | | ceptable | ceptable | lent | lent | lent | lent | |
| Avg space width D_{W1}/ | — | — | 1.18 | 1.06 | 1.08 | 1.06 | 1.06 | 1.03 |
| Min space width D_{W2} | | | | | | | | |
| Avg pattern width P_{W1} | — | — | 1.18 | 1.06 | 1.08 | 1.06 | 1.06 | 1.03 |
| of plating/min pattern width | | | | | | | | |
| P_{W2} of plating | | | | | | | | |
| Avg pattern width F_{W1} | — | — | 1.2 | 1.07 | 1.09 | 1.07 | 1.07 | 1.03 |
| of post-etch plating/min pattern width | | | | | | | | |
| F_{W2} of post-etch plating | | | | | | | | |

TABLE 5

| | Comp | Comp | Comp | Comp | Comp | Comp | Comp | Ref | Comp | Comp |
|---|---|---|---|---|---|---|---|---|---|---|
| | Ex 1 | Ex 2 | Ex 3 | Ex 4 | Ex 5 | Ex 6 | Ex 7 | Ex | Ex 8 | Ex 9 |
| Film name | PET-1 | PET-2 | PET-3 | PET-4 | 16QS68 | 16FB40 | A1517 | R705G-16 | PET-5 | PET-6 |
| Support film thickness [μm] | 16 | 16 | 12 | 16 | 16 | 16 | 16 | 16 | 16 | 16 |
| Composition | 1 | 1 | 1 | 1 | 1 | 1 | 1 | 1 | 1 | 1 |
| Photosensitive resin composition | 15 | 15 | 15 | 15 | 15 | 15 | 15 | 15 | 15 | 15 |
| layer thickness [μm] | | | | | | | | | | |
| Exposure method | Pro- | Pro- | Pro- | Pro- | Pro- | Pro- | Pro- | Pro- | Pro- | Pro- |
| | jection | jection | jection | jection | jection | jection | jection | jection | jection | jection |
| Exposure wavelength | i-line | i-line | i-line | i-line | i-line | i-line | i-line | i-line | i-line | i-line |
| Surface particle number P | 7.70 | 8.00 | 5.40 | 5.20 | 6.90 | 1.00 | 0.90 | 0.90 | 7.30 | 5.20 |
| (P_{A1}/P_{A2}) | | | | | | | | | | |
| Surface particle size S | 3.00 | 2.67 | 2.00 | 1.75 | 2.00 | 0.90 | 0.40 | 0.40 | 2.10 | 1.88 |
| (S_{A1}/S_{A2}) | | | | | | | | | | |
| Developed interfacial ratio Sdr | 7.10 | 5.00 | 5.00 | 3.90 | 3.94 | 0.91 | 18.11 | 4.42 | 4.60 | 4.40 |
| (Sdr_{A1}/Sdr_{A2}) | | | | | | | | | | |
| Developed interfacial ratio | 0.0071 | 0.0065 | 0.0065 | 0.0063 | 0.0078 | 0.008 | 0.0163 | 0.0062 | 0.011 | 0.018 |
| Sdr_{A1} [%] | | | | | | | | | | |
| Support adhesive strength | Unac- | Unac- | Unac- | Unac- | Unac- | Ac- | Unac- | Unac- | Unac- | Unac- |
| | ceptable | ceptable | ceptable | ceptable | ceptable | ceptable | ceptable | ceptable | ceptable | ceptable |
| Resist side surface | OK | OK | OK | OK | OK | OK | OK | OK | OK | OK |
| protrusion number | | | | | | | | | | |
| Avg space width D_{W1}/ | 1.15 | 1.15 | 1.15 | 1.14 | 1.15 | 1.16 | 1.2 | 1.14 | 1.18 | 1.06 |
| Min space width D_{W2} | | | | | | | | | | |
| Avg pattern width P_{W1} | 1.15 | 1.15 | 1.15 | 1.14 | 1.15 | 1.16 | 1.2 | 1.14 | 1.18 | 1.06 |
| of plating/min pattern width | | | | | | | | | | |
| P_{W2} of plating | | | | | | | | | | |
| Avg pattern width F_{W1} | 1.17 | 1.17 | 1.17 | 1.16 | 1.17 | 1.18 | 1.22 | 1.16 | 1.2 | 1.07 |
| of post-etch plating/min pattern width | | | | | | | | | | |
| F_{W2} of post-etch plating | | | | | | | | | | |

TABLE 6

| Film | |
|---|---|
| name | Summary |
| PET-1 | Biaxially stretched polyester film having large-particle surface and small-particle |
| | surface, the small-particle surface having the same particle size, narrower particle |
| | size distribution, and lower particle concentration as compared to 16QS68 |
| | (small-particle surface) |
| PET-2 | Biaxially stretched polyester film having large-particle surface and small-particle |
| | surface, the small-particle surface having smaller particle size than 16QS68 (small- |
| | particle surface) |
| PET-3 | Biaxially stretched polyester film having large-particle surface and small-particle |
| | surface, the small-particle surface having the same particle size and lower particle |
| | concentration as compared to PET-3 |
| PET-4 | Biaxially stretched polyester film having large-particle surface and small-particle |
| | surface, the large-particle surface having smaller particle size than 16QS68 (large- |
| | particle surface) |
| PET-5 | Biaxially stretched polyester film having large-particle surface and particle-free |
| | surface, the particle-free surface being plasma treated |
| PET-6 | Biaxially stretched polyester film having large-particle surface and small-particle |
| | surface, the small-particle surface being plasma-treated |
| 16QS68 | Lumirror ® (manufactured by Toray Industries, Inc.); biaxially stretched polyester |
| | film having large-particle surface and small-particle surface |
| 16FB40 | Lumirror ® (manufactured by Toray Industries, Inc.); biaxially stretched polyester film |
| A1517 | COSMOSHINE ® (manufactured by Toyobo Co., Ltd.); biaxially stretched polyester film |
| R705G-16 | DIAFOIL ® (manufactured by Mitsubishi Chemical Corporation); biaxially stretched |
| | polyester film. |

It was revealed that Examples satisfying formulas (1) to (3) above had high film adhesive strength (high tackiness) and a small number of resist side surface protrusions (excellent resolution).

Conversely, when any of formulas (1) to (3) was not satisfied, i.e., when Sdr_{A1}/Sdr_{A2}≥0.75, P_{A1}/P_{A2}≥0.75, or S_{A1}/S_{A2}≥0.75, the tackiness or resolution was reduced.

Though the embodiments of the present invention have been described above, the present invention is not limited thereto, and the present can be appropriately modified without departing from the spirit of the invention.

### INDUSTRIAL APPLICABILITY

By using the photosensitive element according to the present invention, both high tackiness and high resolution can be achieved, and the present invention can be widely used as a dry film resist in the formation of resist patterns.

What is claimed:

1.-13. (canceled)

14. A photosensitive element, comprising, in this order, a support film (A) and a photosensitive resin composition layer (B), wherein
a developed interfacial ratio Sdr_{A1}(%) of an interface of the support film (A) on an opposite side to that in contact with the photosensitive resin composition layer (B) as defined in ISO 25178 is:
Sdr_{A1}<0.005(%).

15. A photosensitive element, comprising, in this order, a support film (A) and a photosensitive resin composition layer (B), wherein
a developed interfacial ratio Sdr_{A2}(%) of an interface of the support film (A) on a side in contact with the photosensitive resin composition layer (B) and a developed interfacial ratio Sdr_{A1}(%) of an interface thereof on the opposite side as defined in ISO 25178 satisfy the following formula (1):
Sdr_{A1}/Sdr_{A2}<0.75 (1).

16. A photosensitive element, comprising, in this order, a support film (A) and a photosensitive resin composition layer (B), wherein
a surface particle number P_{A2} (particles) of 1.0 μm or more included in an area of 258 μm×260 μm of a surface of the support film (A) on a side in contact with the photosensitive resin composition layer (B) and a surface particle number P_{A1} (particles) of a surface thereof on the opposite side satisfy the following formula (2):
P_{A1}/P_{A2}<0.75 (2).

17. The photosensitive element according to claim 15, wherein a comonomer ratio of a structure having an aromatic ring in a binder of the photosensitive resin composition layer (B) is 50% or more.

18. The photosensitive element according to claim 17, wherein the structure having an aromatic ring is styrene.

19. A resist pattern formation method, comprising the following steps:
a lamination step of laminating the photosensitive element according to claim 15 on a substrate,
an exposure step of exposing a photosensitive resin layer of the photosensitive element, and
a development step of removing an unexposed part of the photosensitive resin layer by development, wherein
the exposure step is carried out by a projection exposure method.

20. A resist pattern formation method, comprising the following steps:
a lamination step of laminating the photosensitive element according to claim 15 on a substrate,
an exposure step of exposing a photosensitive resin layer of the photosensitive element, and
a development step of removing an unexposed part of the photosensitive resin layer by development, wherein
the exposure step is carried out with an exposure wavelength of 405 nm or less.

21. The photosensitive element according to claim 15, wherein
the photosensitive element can be laminated on a copper substrate having a copper shield layer having an average thickness of 1 um or less, and
when the photosensitive element laminated on the copper substrate is subjected to:
(1) exposure using an exposure mask having exposed and unexposed parts with a pitch of 10 μm, and
(2) formation of lines/spaces of a photosensitive resin layer by development after the exposure,
an average space width D_{W1} and a minimum space width D_{W2} satisfy the relationship:
1.00<D_{W1}/D_{W2}<1.10.

22. The photosensitive element according to claim 15, wherein
the photosensitive element can be laminated on a copper substrate having a copper shield layer having an average thickness of 1 urn or less, and when:
(1) exposure using an exposure mask having exposed and unexposed parts with a pitch of 10 μm,
(2) formation of lines/spaces of a photosensitive resin layer by development after the exposure,
(3) formation of a plating pattern by plate processing of the spaces, and
(4) peeling of the photosensitive resin layer from the substrate,
are carried out,
an average pattern width P_{W1} of plating and a minimum pattern width P_{W2} of plating satisfy the relationship:
1.00<P_{W1}/P_{W2}<1.10.

23. The photosensitive element according to claim 15, wherein
the photosensitive element can be laminated on a copper substrate having a copper shield layer having an average thickness of 1 um or less, and when:
(1) exposure using an exposure mask having exposed and unexposed parts with a pitch of 10 μm,
(2) formation of lines/spaces of a photosensitive resin layer by development after the exposure,
(3) formation of a plating pattern by plate processing of the spaces,
(4) peeling of the photosensitive resin layer from the substrate, and
(5) formation of a post-etch plating pattern, which remains after etching of the copper shield layer on the substrate after the peeling of the plating pattern, of the plating pattern, are carried out,
an average pattern width F_{W1} of post-etch plating and a minimum pattern width F_{W2} of post-etch plating satisfy the relationship:
1.00<F_{W1}/F_{W2}<1.10.

24. A method for the formation of a conductor pattern using the photosensitive element according to claim 15, wherein
the photosensitive element can be laminated on a copper substrate having a copper shield layer having a thickness t (urn),
when the photosensitive element laminated on the copper substrate is subjected to:
(1) exposure using an exposure mask having exposed and unexposed parts having a pitch of X (μm), and
(2) formation of lines/spaces of a photosensitive resin layer by development after the exposure, and
an average space width D_{W1} is {(±10% of (X/2))+t} or more, and when
(3) formation of a plating pattern by plate processing of the spaces, and
(4) peeling of the photosensitive resin layer from the substrate,
are carried out,
an average pattern width P_{W1} of plating is within ±10% of the average space width D_{W1}.

25. A wiring pattern formation method, wherein when, after the method for the formation of a conductor pattern according to claim 24,
(5) formation of a post-etch plating pattern, which remains after etching of the copper shield layer on the substrate after the peeling of the plating pattern, of the plating pattern, is carried out,
an average pattern width F_{W1} of post-etch plating is less than the average pattern width P_{W1} of plating.

26. The photosensitive element according to claim 14, wherein a comonomer ratio of a structure having an aromatic ring in a binder of the photosensitive resin composition layer (B) is 50% or more.

27. The photosensitive element according to claim 26, wherein the structure having an aromatic ring is styrene.

28. A resist pattern formation method, comprising the following steps:
a lamination step of laminating the photosensitive element according to claim 14 on a substrate,
an exposure step of exposing a photosensitive resin layer of the photosensitive element, and
a development step of removing an unexposed part of the photosensitive resin layer by development, wherein
the exposure step is carried out by a projection exposure method.

29. A resist pattern formation method, comprising the following steps:
a lamination step of laminating the photosensitive element according to claim 14 on a substrate,
an exposure step of exposing a photosensitive resin layer of the photosensitive element, and
a development step of removing an unexposed part of the photosensitive resin layer by development, wherein
the exposure step is carried out with an exposure wavelength of 405 nm or less.

30. The photosensitive element according to claim 14, wherein
the photosensitive element can be laminated on a copper substrate having a copper shield layer having an average thickness of 1 um or less, and
when the photosensitive element laminated on the copper substrate is subjected to:
(1) exposure using an exposure mask having exposed and unexposed parts with a pitch of 10 μm, and
(2) formation of lines/spaces of a photosensitive resin layer by development after the exposure,
an average space width D_{W1} and a minimum space width D_{W2} satisfy the relationship:
1.00<D_{W1}/D_{W2}<1.10.

31. The photosensitive element according to claim 14, wherein
the photosensitive element can be laminated on a copper substrate having a copper shield layer having an average thickness of 1 um or less, and when:
(1) exposure using an exposure mask having exposed and unexposed parts with a pitch of 10 μm,
(2) formation of lines/spaces of a photosensitive resin layer by development after the exposure,
(3) formation of a plating pattern by plate processing of the spaces, and
(4) peeling of the photosensitive resin layer from the substrate,
are carried out,
an average pattern width P_{W1} of plating and a minimum pattern width P_{W2} of plating satisfy the relationship:
1.00<P_{W1}/P_{W2}<1.10.

32. The photosensitive element according to claim 14, wherein
the photosensitive element can be laminated on a copper substrate having a copper shield layer having an average thickness of 1 urn or less, and when:
(1) exposure using an exposure mask having exposed and unexposed parts with a pitch of 10 μm,
(2) formation of lines/spaces of a photosensitive resin layer by development after the exposure,
(3) formation of a plating pattern by plate processing of the spaces,
(4) peeling of the photosensitive resin layer from the substrate, and
(5) formation of a post-etch plating pattern, which remains after etching of the copper shield layer on the substrate after the peeling of the plating pattern, of the plating pattern,
are carried out,
an average pattern width F_{W1} of post-etch plating and a minimum pattern width F_{W2} of post-etch plating satisfy the relationship:
1.00<F_{W1}/F_{W2}<1.10.

33. A method for the formation of a conductor pattern using the photosensitive element according to claim 14, wherein
the photosensitive element can be laminated on a copper substrate having a copper shield layer having a thickness t (um),
when the photosensitive element laminated on the copper substrate is subjected to:
(1) exposure using an exposure mask having exposed and unexposed parts having a pitch of X (μm), and
(2) formation of lines/spaces of a photosensitive resin layer by development after the exposure, and
an average space width D_{W1} is {(±10% of (X/2))+t} or more, and when
(3) formation of a plating pattern by plate processing of the spaces, and
(4) peeling of the photosensitive resin layer from the substrate,
are carried out,
an average pattern width P_{W1} of plating is within ±10% of the average space width D_{W1}.
